(19) United States
(12) Patent Application Publication
(10) Pub. No.: US 2026/0305448 A1
(43) Pub. Date: Oct. 1, 2026

(54) TEMPORARY PROTECTION FILM FOR SEMICONDUCTOR DEVICE PRODUCTION AND SEMICONDUCTOR DEVICE PRODUCTION METHOD

(71) Applicant: Resonac Corporation, Minato-ku, Tokyo (JP)

(72) Inventors: Shinnosuke TAKEGASA, Tokyo (JP); Kodai ITO, Tokyo (JP)

(21) Appl. No.: 19/477,099

(22) PCT Filed: Aug. 6, 2024
(86) PCT No.: PCT/JP2024/028141

§ 371 Date: Oct. 20, 2025

(30) Foreign Application Priority Data
Aug. 23, 2023 (JP) 2023-135765

(51) Int. Cl. H10W 74/01; B32B 7/12; B32B 9/04; H10P 72/70

(52) U.S. Cl. CPC H10W 74/019; B32B 7/12; B32B 9/045; H10P 72/74; B32B 2457/14

(57) ABSTRACT

A temporary protective film for production of a semiconductor device, comprising a support film and an adhesive layer provided on the support film, wherein the adhesive layer contains an acrylic polymer having a weight-average molecular weight of 550,000 or more and a molecular weight distribution of 2.0 or less.

### TECHNICAL FIELD

The present disclosure relates to a temporary protective film for production of a semiconductor device and a method for producing a semiconductor device.

### BACKGROUND ART

In semiconductor packages, a structure is sometimes adopted in which an encapsulating layer is formed only on the semiconductor element side of the lead frame, and the back surface of the lead frame is exposed. In the production of a semiconductor package having this structure, there is a risk that the encapsulant may spread to the back surface of the lead frame when the encapsulating layer is formed. In order to prevent this, a method is known in which a temporary protective film is attached to the back surface of the lead frame (Patent Literature 1). The temporary protective film is peeled off from the lead frame after the encapsulating layer is formed.

### CITATION LIST

### Patent Literature

Patent Literature 1: International Publication No. WO 2001/035460

### SUMMARY OF INVENTION

### Technical Problem

In a temporary protective film, it is desirable that adhesive components of the temporary protective film do not remain on the lead frame when the temporary protective film is peeled from the lead frame after forming the encapsulating layer. Therefore, an object of one aspect of the present invention is to provide a temporary protective film that can suppress residue on the lead frame during peeling.

### Solution to Problem

According to studies by the present inventors, it has been found that by setting the weight-average molecular weight (Mw) and the molecular weight distribution (Mw/Mn) of the acrylic polymer contained in the adhesive layer of the temporary protective film to be within a specific range, the occurrence of residue on the lead frame can be suppressed compared to a case where an acrylic polymer having an Mw and an Mw/Mn outside the specific range is used.

The present invention includes the following aspects.
[1] A temporary protective film for production of a semiconductor device, comprising a support film and an adhesive layer provided on the support film, wherein the adhesive layer contains an acrylic polymer having a weight-average molecular weight of 550,000 or more and a molecular weight distribution of 2.0 or less.
[2] The temporary protective film according to [1], wherein the acrylic polymer contains alkyl (meth)acrylate and (meth)acryloylmorpholine as monomer units.
[3] The temporary protective film according to [1] or [2], wherein the weight-average molecular weight of the acrylic polymer is 850,000 or more.
[4] A method for producing a semiconductor device, comprising: attaching a temporary protective film to one surface side of a substrate; mounting a semiconductor element on a surface of the substrate opposite to the temporary protective film; encapsulating the semiconductor element; and peeling the temporary protective film from the substrate, in this order, wherein the temporary protective film comprises a support film and an adhesive layer provided on the support film, and the adhesive layer contains an acrylic polymer having a weight-average molecular weight of 550,000 or more and a molecular weight distribution of 2.0 or less.
[5] The method according to [4], wherein the acrylic polymer includes alkyl (meth)acrylate and (meth)acryloylmorpholine as monomer units.
[6] The method according to [4] or [5], wherein the weight-average molecular weight of the acrylic polymer is 850,000 or more.

### Advantageous Effects of Invention

According to one aspect of the present invention, it is possible to provide a temporary protective film that can suppress residue on the lead frame during peeling.

### BRIEF DESCRIPTION OF DRAWINGS

FIG. 1 is a cross-sectional view showing an embodiment of a temporary protective film.

FIG. 2 is a cross-sectional view for illustrating an embodiment of a method for producing a semiconductor device.

FIG. 3 is a cross-sectional view for illustrating an embodiment of a method for producing a semiconductor device.

FIG. 4 is a cross-sectional view showing an embodiment of a semiconductor device.

FIG. 5 is a perspective view showing an embodiment of a reel body.

### DESCRIPTION OF EMBODIMENTS

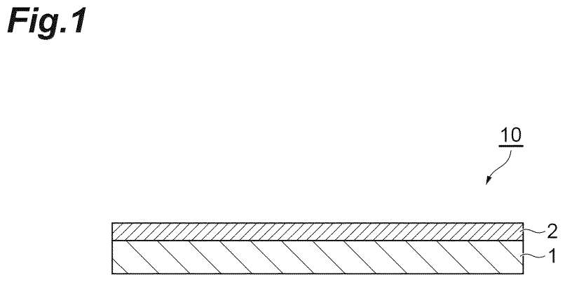

Hereinafter, embodiments of the present invention will be described. FIG. 1 is a cross-sectional view showing a temporary protective film according to an embodiment. As shown in FIG. 1, a temporary protective film 10 according to an embodiment comprises a support film 1 and an adhesive layer 2 provided on the support film 1. The temporary protective film 10 can be used as a temporary protective film for production of a semiconductor device. More specifically, the temporary protective film 10 can be used as a temporary protective film for semiconductor encapsulation molding for temporarily protecting a lead frame during encapsulation molding, by being attached to the back surface of the lead frame (the surface opposite to the surface on which a semiconductor element is mounted) in the step of encapsulation molding for forming an encapsulating layer that encapsulates the semiconductor element mounted on a die pad of the lead frame.

The support film 1 may be, for example, a film of at least one polymer selected from the group consisting of polyimide, polyamide, polyamide-imide, polysulfone, polyethersulfone, polyphenylene sulfide, polyetherketone, polyarylate, polyetheretherketone, and polyethylene naphthalate, and may preferably be a film of polyimide. The polyimide may be an aromatic polyimide. The support film 1 may be a film of copper, aluminum, stainless steel, or nickel. When the support film 1 is a polymer film, its surface may be surface-treated by a method such as a chemical treatment like alkali treatment or silane coupling treatment, a physical treatment like sand mat treatment, a plasma treatment, or a corona treatment.

The thickness of the support film 1 may be, for example, 5 μm or more, and may be 100 μm or less or 50 μm or less. The ratio T₂/T₁ of the thickness T₂ of the adhesive layer 2 to the thickness T₁ of the support film 1 may be 0.1 or more, and may be 0.5 or less, 0.3 or less, or 0.2 or less.

The adhesive layer 2 contains an acrylic polymer having a weight-average molecular weight (Mw) of 550,000 or more and a molecular weight distribution (Mw/Mn) of 2.0 or less.

The Mw of the acrylic polymer may be 600,000 or more, and from the viewpoint of also being able to suppress the residue of adhesive components on the encapsulating layer after peeling the temporary protective film from the lead frame and the encapsulating layer even when the thickness of the adhesive layer 2 is thin (for example, about 2 μm), it is preferably 650,000 or more, more preferably 750,000 or more, still more preferably 850,000 or more, and particularly preferably 950,000 or more. The Mw of the acrylic polymer may be 2,000,000 or less, 1,800,000 or less, 1,600,000 or less, 1,400,000 or less, 1,200,000 or less, or 1,100,000 or less.

From the viewpoint of being able to further suppress residue on the lead frame, the Mw/Mn of the acrylic polymer may preferably be 1.9 or less, 1.8 or less, or 1.7 or less. The Mw/Mn of the acrylic polymer may be 1.0 or more, 1.2 or more, 1.4 or more, or 1.6 or more.

The Mw and Mw/Mn of the acrylic polymer are measured by the following procedure.

The values were determined by gel permeation chromatography (GPC) using a high-performance liquid chromatograph (manufactured by Tosoh Corporation, model HLC-8320GPC). Two TSKgel Super Multipore HZ-H columns (manufactured by Tosoh Corporation) are used, with a tetrahydrofuran solution as the mobile phase and a differential refractometer as the detector. The measurement conditions are a column temperature of 40° C., a sample concentration of 10 mg/mL, a sample injection volume of 10 μm, and a flow rate of 0.2 mL/min. A calibration curve is prepared using polystyrene as a standard substance (molecular weights: 1,090,000, 775,000, 427,000, 289,000, 190,000, 96,400, 37,900, 10,200, 2,630, 440), and the weight-average molecular weight (Mw) and the number-average molecular weight (Mn) are measured. The molecular weight distribution (Mw/Mn) is calculated from these measured values.

The acrylic polymer is a polymer including at least alkyl (meth)acrylate as monomer units, and may be a polymer including other monomers as monomer units in addition to alkyl (meth)acrylate.

The alkyl group in the alkyl (meth)acrylate (the alkyl group portion other than the (meth)acryloyl group) may be linear or branched. The number of carbon atoms in the alkyl group may be 2 or more or 3 or more, may be 30 or less, 20 or less, 10 or less, 7 or less, 5 or less, or 4 or less, and may be 2 or 4.

Examples of the alkyl (meth)acrylate include methyl (meth)acrylate, ethyl (meth)acrylate, propyl (meth)acrylate, butyl (meth)acrylate, pentyl (meth)acrylate, n-hexyl (meth)acrylate, n-heptyl (meth)acrylate, n-octyl (meth)acrylate, 2-ethylhexyl (meth)acrylate, nonyl (meth)acrylate, and decyl (meth)acrylate.

The content of the alkyl (meth)acrylate may be 70% by mass or more, 75% by mass or more, or 80% by mass or more, and may be 92% by mass or less, 90% by mass or less, or 88% by mass or less, based on the total amount of monomer units in the acrylic polymer.

From the viewpoint of being able to further suppress residue on the lead frame during peeling of the temporary protective film, the other monomers preferably include (meth)acryloylmorpholine. That is, from the same viewpoint, the acrylic polymer preferably includes alkyl (meth)acrylate and (meth)acryloylmorpholine as monomer units.

The content of (meth)acryloylmorpholine may be 7% by mass or more, 7.5% by mass or more, 8% by mass or more, 8.5% by mass or more, or 9.0% by mass or more, and may be 20% by mass or less, 18% by mass or less, 17% by mass or less, 16.5% by mass or less, or 16% by mass or less, based on the total amount of monomer units in the acrylic polymer. The mass ratio of the content of (meth)acryloylmorpholine to the content of alkyl (meth)acrylate ((meth)acryloylmorpholine/alkyl (meth)acrylate) may be 0.08/1 or more, 0.09/1 or more, or 0.1/1 or more, and may be 0.3/1 or less, 0.25/1 or less, 0.23/1 or less, 0.21/1 or less, or 0.2/1 or less.

The other monomers may include a monomer having a cross-linkable group (cross-linkable monomer). The cross-linkable monomer has a polymerizable group copolymerizable with alkyl (meth)acrylate and (meth)acryloylmorpholine, in addition to the cross-linkable group. The polymerizable group may be, for example, an ethylenically unsaturated group. The cross-linkable group may be, for example, an acidic group. The acidic group may be, for example, a carboxyl group or a sulfo group, and is preferably a carboxyl group.

Examples of the cross-linkable monomer having a carboxyl group include (meth)acrylic acid, carboxyethyl (meth)acrylate, carboxypentyl (meth)acrylate, monohydroxyethyl acrylate phthalate, and 2-acryloyloxyethyl succinate.

The content of the cross-linkable monomer may be 1% by mass or more, 2% by mass or more, or 3% by mass or more, and may be 10% by mass or less, 6% by mass or less, or 4% by mass or less, based on the total amount of monomer units in the acrylic polymer.

The other monomers may include, for example, a monomer having a polymerizable group (e.g., an ethylenically unsaturated group) and a hydroxyl group. Examples of this monomer include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate; and hydroxyalkylcycloalkane (meth)acrylates such as (4-hydroxymethylcyclohexyl) methyl (meth)acrylate.

The acid value of the acrylic polymer may be 10 mgKOH/g or more or 20 mgKOH/g or more, and may be 40 mgKOH/g or less or 30 mgKOH/g or less. The hydroxyl value of the acrylic polymer may be 1 mgKOH/g or more or 2 mgKOH/g or more, and may be 10 mgKOH/g or less or 5 mgKOH/g or less. The acid value and hydroxyl value of the acrylic polymer are measured in accordance with the method described in JIS K0070.

The content of the acrylic polymer may be 80% by mass or more, 85% by mass or more, or 90% by mass or more, and may be 99.5% by mass or less or 99% by mass or less, based on the total amount of the adhesive layer 2.

The adhesive layer 2 may further contain a cross-linking agent, or may not contain a cross-linking agent. The cross-linking agent is a cross-linking agent that is cross-linkable with the cross-linkable groups in the acrylic polymer. As such a cross-linking agent, a known cross-linking agent can be used. When the cross-linkable group in the acrylic polymer is an acidic group, the cross-linking agent preferably has an epoxy group. The number of epoxy groups in the cross-linking agent may be 2 or more or 3 or more, may be 4 or less, and may be 4.

In one embodiment, the cross-linking agent may be a cross-linking agent having an amino group in addition to an epoxy group. The amino group may be a substituted amino group in which a hydrogen atom in a —NH₂ group is substituted, and may be a tertiary amino group. Such a cross-linking agent may have a group represented by the following formula (1).

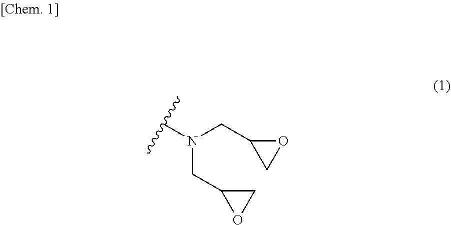 [SMILES: *N(CC1CO1)CC1CO1]

The number of groups represented by the above formula (1) in the cross-linking agent may be 1 or 2.

The cross-linking agent may be a cross-linking agent represented by the following formula (2).

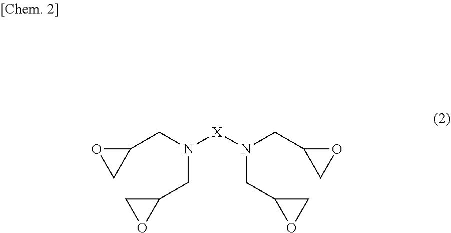

In the formula, X represents a divalent hydrocarbon group.

The divalent hydrocarbon group represented by X may be a divalent hydrocarbon group having a ring. The ring may be an alicyclic ring or an aromatic ring. The number of carbon atoms constituting the ring may be 5 or more, may be 8 or less, and may be 6. The number of rings in the divalent hydrocarbon group may be 1 or more, may be 3 or less, and may be 1 or 2. When the divalent hydrocarbon group includes a plurality of rings, the plurality of rings may be directly bonded to each other, or may be bonded via an alkylene group having 1 to 3 carbon atoms.

The divalent hydrocarbon group represented by X preferably contains a cycloalkylene group. The number of carbon atoms of the cycloalkylene group may be 5 or more, and may be 8 or less. The cycloalkylene group is preferably a cyclohexylene group.

In one embodiment, the cross-linking agent may be a cross-linking agent having an ether group in addition to an epoxy group (and not having an amino group). Such a cross-linking agent may have a group represented by the following formula (3).

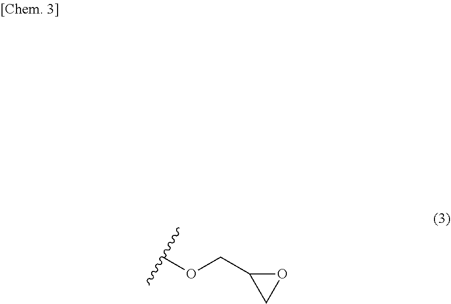 [SMILES: *OCC1CO1]

The number of groups represented by the above formula (3) in the cross-linking agent may be 2 or more or 3 or more, may be 4 or less, and may be 2 or 4.

The cross-linking agent may be a cross-linking agent represented by the following formula (4).

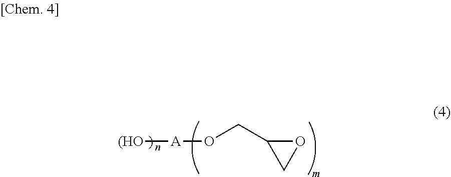

In the formula, m represents an integer of 2 or more, n represents an integer of 0 or more, and A represents a residue obtained by removing hydroxyl groups from a polyhydric alcohol having a valence of m+n.

m may be an integer of 3 or more, may be an integer of 4 or less, and may be 2 or 4. n may be an integer of 1 or more, may be an integer of 2 or less, and may be 0 or 2. m+n may be an integer of 2 or more, and may be an integer of 6 or less.

The polyhydric alcohol in A may be an aliphatic polyhydric alcohol or an alicyclic polyhydric alcohol, and may be a polyhydric alcohol having an ether group. The number of carbon atoms of the aliphatic polyhydric alcohol or the alicyclic polyhydric alcohol may be 2 or more, 3 or more, or 4 or more, and may be 10 or less, 9 or less, or 8 or less. The polyhydric alcohol having an ether group may be a polyalkylene glycol such as polyethylene glycol.

The content of the cross-linking agent may be 0.5% by mass or more, and may be 15% by mass or less or 10% by mass or less, based on the total amount of the adhesive layer 2, and from the viewpoint of suppressing deterioration of the appearance of the adherend after peeling the temporary protective film from the adherend, it is preferably 1% by mass or more, 2% by mass or more, or 2.5% by mass or more.

The content of the cross-linking agent may be 0.5 parts by mass or more, and may be 15 parts by mass or less or 10 parts by mass or less, with respect to 100 parts by mass of the content of the acrylic polymer, and from the viewpoint of suppressing deterioration of the appearance of the adherend after peeling the temporary protective film from the adherend, it is preferably 1 part by mass or more, 2 parts by mass or more, or 3 parts by mass or more.

The adhesive layer 2 may further contain other components other than the acrylic polymer and the cross-linking agent. Examples of other components include polymers other than the acrylic polymer and coupling agents.

The thickness of the adhesive layer 2 may be 1 μm or more or 2 μm or more, and may be 20 μm or less, 15 μm or less, 10 μm or less, 5 μm or less, 4 μm or less, or 3 μm or less.

In another embodiment, the temporary protective film may further comprise a cover film provided on the surface of the adhesive layer opposite to the support film. That is, the temporary protective film may comprise a support film, an adhesive layer, and a cover film in this order. The cover film may be a polyethylene terephthalate film. The thickness of the cover film may be 10 μm or more, and may be 100 μm or less.

In another embodiment, the temporary protective film may further comprise a non-adhesive layer provided on the side of the support film opposite to the adhesive layer. The non-adhesive layer may be a resin layer that has substantially no adhesiveness to an adherend at 0 to 270° C. The non-adhesive layer may include a resin that is a thermoplastic resin, a thermosetting resin (cured product), or a combination thereof. The non-adhesive layer may further contain a filler (e.g., ceramic powder, glass powder, silver powder, copper powder, resin particles, rubber particles), a coupling agent, or the like. The thickness of the non-adhesive layer may be 1 μm or more, and may be 10 μm or less.

The temporary protective film can be produced, for example, by a method including a step of forming the adhesive layer by applying a varnish containing an acrylic polymer and a cross-linking agent onto a support film and removing the solvent from the coating film.

Next, a method for producing a semiconductor device using the above-described temporary protective film will be described. A method for producing a semiconductor device of one embodiment comprises, in the following order: a step S1 of attaching a temporary protective film to one surface side of a substrate; a step S2 of mounting a semiconductor element on a surface of the substrate opposite to the temporary protective film; a step S3 of encapsulating the semiconductor element; and a step S4 of peeling the temporary protective film from the substrate. Hereinafter, as an example, a method for producing a semiconductor device (semiconductor device package) in a case where the substrate is a lead frame will be described more specifically.

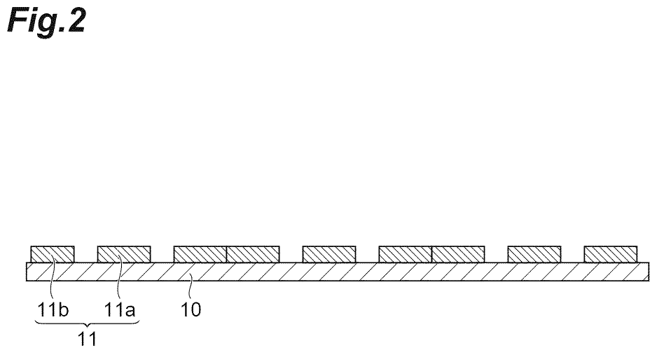

FIG. 2 is a cross-sectional view for explaining an embodiment (step S1) of the method for producing a semiconductor device. In step S1, as shown in FIG. 2, a temporary protective film 10 is attached to the back surface, which is one surface of a lead frame 11 having a die pad 11a and inner leads 11b. The temporary protective film 10 is attached in such a manner that the adhesive layer of the temporary protective film 10 is in contact with the lead frame 11.

The lead frame 11 may be formed from, for example, an iron-based alloy such as Alloy 42, copper, or a copper-based alloy. The lead frame 11 may have a molded body formed from copper or a copper-based alloy, and a coating layer of palladium, gold, silver, or the like covering its surface.

Since the temporary protective film 10 is excellent in adhesive strength at room temperature (e.g., 25° C.), it can be attached to the lead frame 11 at room temperature. The temporary protective film 10 may be attached to the lead frame 11 while performing heating and pressurization. In this case, the heating temperature may be 150° C. or higher, and may be 400° C. or lower. The pressure may be 0.5 MPa or higher, and may be 30 MPa or lower. The time for heating and pressurization may be 1 second or longer, and may be 60 seconds or shorter.

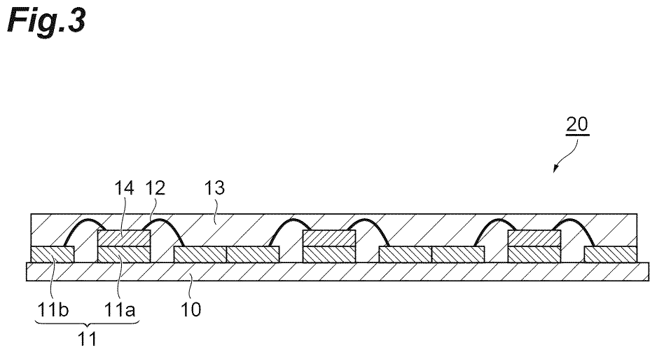

FIG. 3 is a cross-sectional view for explaining an embodiment (step S2 and step S3) of the method for producing a semiconductor device. In step S2, as shown in FIG. 3, a semiconductor element 14 is mounted on the surface of the die pad 11a on the side opposite to the temporary protective film 10. The semiconductor element 14 is adhered to the die pad 11a via an adhesive (for example, silver paste). After adhering the semiconductor element 14 to the die pad 11a, reflow connection (CuClip connection, etc.) may be performed under conditions of a maximum temperature of 250 to 440° C., or 250 to 400° C., and for 1 to 30 minutes.

Next, the semiconductor element 14 is connected to the inner leads 11b using a wire 12. The wire 12 may be, for example, a gold wire, a copper wire, or a palladium-coated copper wire. The wire 12 may be bonded to the semiconductor element 14 and the inner lead 11b using ultrasonic waves and pushing pressure while performing heating at, for example, 200 to 350° C.

Subsequently, in step S3, as shown in FIG. 3, an encapsulating layer 13 that encapsulates the semiconductor element 14 and the wire 12 is formed. Thus, a temporarily protected encapsulation molding product 20 having the lead frame 11, the semiconductor element 14, and the encapsulating layer 13 is obtained.

The encapsulating layer 13 is formed by encapsulation molding using an encapsulant. By encapsulation molding, an encapsulation molding product 20 having a plurality of semiconductor elements 14 and an encapsulating layer 13 that encapsulates them all at once can be obtained. During the encapsulation molding, the provision of the temporary protective film 10 suppresses the encapsulant from wrapping around to the back surface side of the lead frame 11.

The temperature during the formation of the encapsulating layer 13 (temperature of the encapsulant) may be 140 to 200° C., or 160 to 180° C. The pressure during the formation of the encapsulating layer may be 6 to 15 MPa, or 7 to 10 MPa. The time for encapsulation molding may be 1 to 5 minutes, or 2 to 3 minutes.

The encapsulant may contain, for example, an epoxy resin such as a cresol novolac epoxy resin, a phenol novolac epoxy resin, a biphenyl diepoxy resin, or a naphthol novolac epoxy resin. The encapsulant may contain a filler, a flame retardant substance such as a bromine compound, a wax component, or the like.

After the formation of the encapsulating layer 13 (encapsulation molding), the temporary protective film 10 is peeled from the lead frame 11 and the encapsulating layer 13 of the obtained encapsulation molding product 20. When curing the encapsulating layer 13, the temporary protective film 10 may be peeled either before or after the curing of the encapsulating layer 13.

The temperature at which the temporary protective film 10 is peeled is not particularly limited, but may be room temperature (e.g., 5 to 35° C.), or may be equal to or higher than the glass transition temperature (Tg) of the adhesive layer. In this case, the temporary protective film 10 is peeled off from the lead frame 11 and the encapsulant even more favorably. If the Tg of the acrylic polymer in the adhesive layer is, for example, 5° C. or lower, or 0° C. or lower, the Tg of the adhesive layer becomes equal to or lower than room temperature, and the temporary protective film tends to be peeled favorably at room temperature.

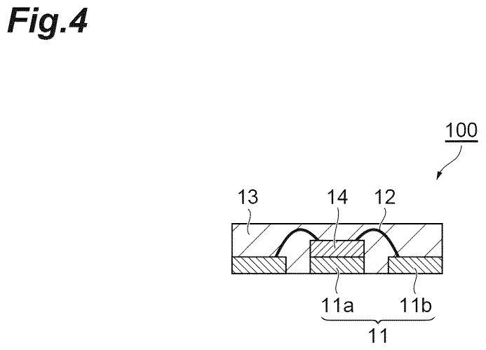

When the lead frame 11 includes a plurality of patterns having die pads 11a and inner leads 11b, the encapsulation molding product 20 can be divided as necessary to obtain a plurality of semiconductor devices (semiconductor packages) 100 of FIG. 4, each having one semiconductor element. That is, when the lead frame 11 has a plurality of die pads 11a and a semiconductor element 14 is mounted on each of the plurality of die pads 11a, the production method according to one embodiment may further comprise obtaining a semiconductor device (semiconductor package) 100 having one die pad 11a and one semiconductor element 14 by dividing the encapsulation molding product 20 after peeling the temporary protective film 10 from the encapsulation molding product 20.

The temporary protective film may be in a long strip shape and used in the state of a reel body wound on a core. In this case, the temporary protective film is attached to an adherend while being unwound from the reel body.

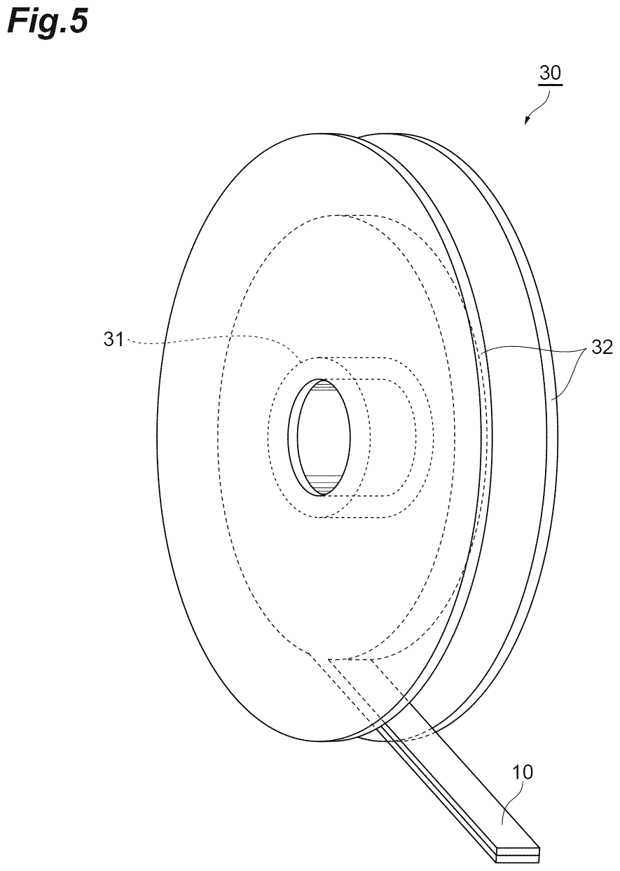

FIG. 5 is a perspective view showing an embodiment of a reel body. As shown in FIG. 5, a reel body 30 according to one embodiment comprises a core 31, a temporary protective film 10 wound on the core 31, and side plates 32. The width of the core 31 and the temporary protective film 10 (the length in the direction orthogonal to the winding direction) may be 1 mm or more, 5 mm or more, or 10 mm or more, and may be 1000 mm or less, 800 mm or less, or 500 mm or less. In another embodiment, the reel body may not comprise side plates.

### EXAMPLES

Hereinafter, the present invention will be described more specifically with reference to Examples. However, the present invention is not limited to the Examples.

### Example 1

An acrylic polymer A-1 having a weight-average molecular weight (Mw) of 600,000 and a molecular weight distribution (Mw/Mn) of 1.7 was dissolved in cyclohexanone to obtain a varnish for forming an adhesive layer. The acrylic polymer A-1 is a copolymer of butyl acrylate/acryloylmorpholine/acrylic acid/other monomer (monomer having a hydroxyl group)=80/16/3/1 (mass ratio). As a support film, a polyimide film (thickness: 25 μm, manufactured by Toray-DuPont Co., Ltd., trade name: Kapton 100EN) was prepared. The obtained varnish was applied onto one surface of the support film. The coating film on the support film was dried by heating at 90° C. for 1.5 minutes and at 260° C. for 1.5 minutes to form an adhesive layer with a thickness of 2 μm. A temporary protective film was thereby obtained.

### Examples 2-3

Temporary protective films were obtained in the same manner as in Example 1, except that the thickness of the adhesive layer was changed as shown in Table 1.

### Example 4

A temporary protective film was obtained in the same manner as in Example 1, except that a varnish was prepared by adding 10 parts by mass of a cross-linking agent B-1 represented by the following formula (B-1) to 100 parts by mass of the acrylic polymer A-1, and the thickness of the adhesive layer was changed as shown in Table 1.

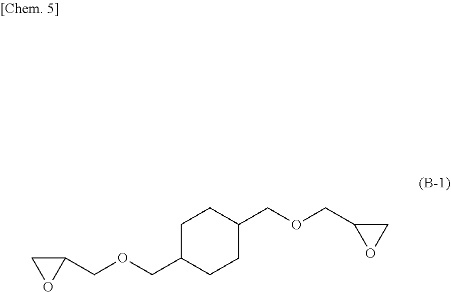 [SMILES: C1CC(COCC2CO2)CCC1COCC1CO1]

### Example 5

A temporary protective film was obtained in the same manner as in Example 4, except that 7 parts by mass of a cross-linking agent B-2 represented by the following formula (B-2) was added instead of 10 parts by mass of the cross-linking agent B-1.

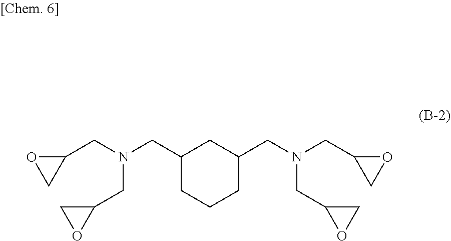 [SMILES: C1CC(CN(CC2CO2)CC2CO2)CC(CN(CC2CO2)CC2CO2)C1]

### Example 6

A temporary protective film was obtained in the same manner as in Example 1, except that an acrylic polymer A-2 having a weight-average molecular weight (Mw) of 1,000,000 and a molecular weight distribution (Mw/Mn) of 1.9 was used instead of the acrylic polymer A-1. The acrylic polymer A-2 is a copolymer of butyl acrylate/acryloylmorpholine/acrylic acid/other monomer (monomer having a hydroxyl group)=80/16/3/1 (mass ratio).

### Examples 7-8

Temporary protective films were obtained in the same manner as in Example 6, except that the thickness of the adhesive layer was changed as shown in Table 1.

### Comparative Example 1

A temporary protective film was obtained in the same manner as in Example 1, except that a varnish was prepared using 100 parts by mass of an acrylic polymer a-1 (trade name: HTR-280, manufactured by Nagase ChemteX Corporation) having a weight-average molecular weight (Mw) of 990,000 and a molecular weight distribution (Mw/Mn) of 3.0, and 30 parts by mass of a cross-linking agent B-3 represented by the following formula (B-3), instead of 100 parts by mass of the acrylic polymer A-1, and the thickness of the adhesive layer was changed as shown in Table 1.

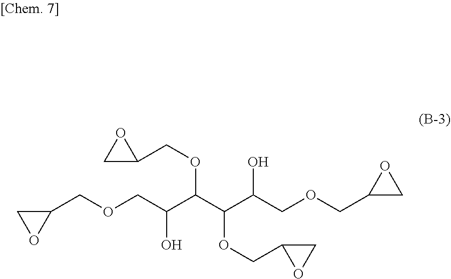 [SMILES: OC(COCC1CO1)C(OCC1CO1)C(OCC1CO1)C(O)COCC1CO1]

### Comparative Example 2

A temporary protective film was obtained in the same manner as in Example 1, except that a varnish was prepared using 30 parts by mass of the acrylic polymer a-1, 70 parts by mass of an acrylic polymer a-2 (trade name: WS-023 EK30, manufactured by Nagase ChemteX Corporation) having a weight-average molecular weight (Mw) of 720,000 and a molecular weight distribution (Mw/Mn) of 4.4, and 10 parts by mass of the cross-linking agent B-3, instead of 100 parts by mass of the acrylic polymer A-1, and the thickness of the adhesive layer was changed as shown in Table 1.

### (Evaluation of Residue)

Each temporary protective film was attached to a CDA194 palladium-plated Cu plate (lead frame, manufactured by Shinko Electric Industries Co., Ltd.) at 25° C. under a load of 20 N, with the adhesive layer facing the lead frame. The obtained laminate was heated in an oven in an air atmosphere, with the conditions changed in the order of 180° C. for 60 minutes, then 200° C. for 60 minutes. The surface of the lead frame opposite to the temporary protective film was plasma-treated under an argon gas atmosphere (flow rate: 20 sccm) at 150 W for 15 seconds.

Using a molding machine (manufactured by Apic Yamada Corporation), an encapsulating layer was formed with an encapsulant (trade name: GE-300, manufactured by Showa Denko Materials Co., Ltd.) on the surface of the lead frame opposite to the temporary protective film. The encapsulation conditions were 175° C., 6.8 MPa, for 2 minutes. Thereafter, at 25° C., each temporary protective film was peeled off at a speed of 50 mm/min in a direction of 180° with respect to the surface of the lead frame. The state of the adhesive layer remaining on the lead frame and on the encapsulating layer after peeling the temporary protective film was confirmed. The ratio of the area occupied by the residue of the adhesive layer to the surface area of the lead frame and the surface area of the encapsulating layer, respectively, was determined. Evaluation was made based on the following criteria according to the ratio of the area occupied by the residue. The results are shown in Table 1.
A: Less than 5%
B: 5% or more and less than 15%
C: 15% or more

TABLE 1

| | | | | | | | | | Comparative | |
|---|---|---|---|---|---|---|---|---|---|---|
| | Example | | | | | | | | Example | |
| | 1 | 2 | 3 | 4 | 5 | 6 | 7 | 8 | 1 | 2 |
| Type of acrylic | A-1 | A-1 | A-1 | A-1 | A-1 | A-2 | A-2 | A-2 | a-1 | a-1/ a-2 |
| polymer | | | | | | | | | | |
| Type of cross-linking | — | — | — | B-1 | B-2 | — | — | — | B-3 | B-3 |
| agent | | | | | | | | | | |
| Thickness of adhesive | 2 | 3 | 4 | 5 | 5 | 2 | 3 | 4 | 5 | 5 |
| layer (μm) | | | | | | | | | | |
| Residue on lead frame | A | A | A | A | A | A | A | A | C | C |
| Residue on | C | A | A | A | B | A | A | A | C | C |
| encapsulating layer | | | | | | | | | | |

### REFERENCE SIGNS LIST

1 . . . support film, 2 . . . adhesive layer, 10 . . . temporary protective film, 11 . . . lead frame, 11a . . . die pad, 11b . . . inner lead, 12 . . . wire, 13 . . . encapsulating layer, 14 . . . semiconductor element, 20 . . . encapsulation molding product, 100 . . . semiconductor device.

1. A temporary protective film for production of a semiconductor device, comprising:
a support film; and
an adhesive layer provided on the support film,
wherein the adhesive layer contains an acrylic polymer having a weight-average molecular weight of 550,000 or more and a molecular weight distribution of 2.0 or less.

2. The temporary protective film according to claim 1, wherein the acrylic polymer includes alkyl (meth)acrylate and (meth)acryloylmorpholine as monomer units.

3. The temporary protective film according to claim 1, wherein the weight-average molecular weight of the acrylic polymer is 850,000 or more.

4. A method for producing a semiconductor device, comprising:
attaching a temporary protective film to one surface side of a substrate;
mounting a semiconductor element on a surface of the substrate opposite to the temporary protective film;
encapsulating the semiconductor element; and
peeling the temporary protective film from the substrate,
wherein the temporary protective film comprises:
a support film; and
an adhesive layer provided on the support film, and
the adhesive layer contains an acrylic polymer having a weight-average molecular weight of 550,000 or more and a molecular weight distribution of 2.0 or less.

5. The method according to claim 4, wherein the acrylic polymer includes alkyl (meth)acrylate and (meth)acryloylmorpholine as monomer units.

6. The method according to claim 4, wherein the weight-average molecular weight of the acrylic polymer is 850,000 or more.
